(19) United States
(12) Patent Application Publication
(10) Pub. No.: US 2019/0182905 A1
(43) Pub. Date: Jun. 13, 2019

(54) INFRARED HEATING LAMP TUBE DEVICE

(71) Applicant: Beijing Chuangyu Technology Co., Ltd., Beijing (CN)

(72) Inventor: Zhiqing Dong, Beijing (CN)

(21) Appl. No.: 16/123,331

(22) Filed: Sep. 6, 2018

(30) Foreign Application Priority Data
Dec. 13, 2017 (CN) 201711326719.4

(51) Int. Cl. H05B 3/00; C23C 16/48

(52) U.S. Cl. CPC H05B 3/0038; C23C 16/482

(57) ABSTRACT

The present disclosure relates to the technical field of infrared heating lamp tube, particularly to an infrared heating lamp tube device. The infrared heating lamp tube device includes a mounting base plate and a plurality of infrared heating lamp tubes mounted on the mounting base plate, wherein the plurality of infrared heating lamp tubes are radially arranged in a circumferential direction with a center of the mounting base plate as a circle center, and an extension line of each infrared heating lamp tube is directed toward the center of the mounting base plate. By arranging a plurality of infrared heating lamp tubes radially in a circumferential direction with the center of the mounting base plate as a circle center, the infrared heating lamp tube device described of the present disclosure can achieve a better control of temperature uniformity and meet the requirement of higher process uniformity.

### CLAIM OF PRIORITY

This application claims priority to Chinese Patent Application No. 201711326719.4, filed Dec. 13, 2017, the entire contents of which are fully incorporated herein by reference.

### TECHNICAL FIELD

The present disclosure relates to the technical field of infrared heating lamp tube, particularly to an infrared heating lamp tube device.

### BACKGROUND

Photovoltaic devices, solar devices and semiconductor devices are typically manufactured by processing the substrate surfaces with a variety of manufacturing techniques. The method is widely used that the epitaxial film or material is grown or deposited on the substrate by chemical vapor deposition CVD process or metal organic CVD process. Epitaxial films or materials generally include layers of different compositions for specific devices such as photovoltaic devices, solar devices, and the like.

CVD techniques are often classified by the reaction type or pressure, including low pressure CVD, atmospheric pressure CVD, plasma enhanced CVD and metal organic compound CVD and so on. The common features thereof are that the chamber for technical deposition is isolated from the atmosphere, and the wafer substrate for the process of depositing the thin film needs to be heated to a certain process temperature. Therefore, how to maintain the temperature uniformity at high temperatures will have a significant impact on the process results.

For a flat reaction chamber, the wafer substrate is transferred into the process deposition chamber by the wafer carrier along the wafer carrier track, and the lower surface of the wafer susceptor for supporting the wafer substrate is exposed to the energy radiated from the heating lamp assembly, meanwhile the wafer substrate is heated to the process temperature by the wafer susceptor. The infrared heating lamp assembly is disposed below the wafer carrier track, including a plurality of infrared heating lamp tubes with the same mounting height. Each lamp tube can be independently connected to the power supply and controlled, that is, the amount of electricity flowing to each lamp tube can be independently adjusted by the controller.

However, the existing infrared heating lamp tubes generally employ a parallel arrangement, so that the heating area of the lamp tubes covers the entire wafer area and even the support plate area. For the parallel arrangement of the infrared heating lamp tubes, it is possible to independently adjust the electricity amount of each lamp tube to control the energy radiated by the lamp tube, but only the temperature distribution in the direction of the parallel arrangement of the lamp tubes can be adjusted, while the temperature distribution in the direction vertical to the arrangement of the lamp tubes cannot be adjusted. The power cannot be adjusted in the length direction of each lamp tube. Therefore the temperature distribution in this direction cannot be adjusted; and thus, the temperature distribution still cannot meet higher uniformity requirements in the existing control technology.

### SUMMARY

### (I) Technical Problem to be Solved

One objective of the present disclosure is to provide an infrared heating lamp tube device, so as to provide a parallel arrangement of the infrared heating lamp tubes that can meet the requirement of higher temperature distribution uniformity.

### (II) Technical Solutions

One of the embodiments of the present disclosure provides an infrared heating lamp tube device, including a mounting base plate and a plurality of infrared heating lamp tubes mounted on the mounting base plate. The plurality of the infrared heating lamp tubes are radially arranged in a circumferential direction with a center of the mounting base plate as a circle center, and an extension line of each infrared heating lamp tube is directed toward the center of the mounting base plate.

In one of the embodiments, the infrared heating lamp tubes are divided into at least two groups, an end of each group of the infrared heating lamp tubes pointing to the center of the mounting base plate forms a circle, and each circle is arranged in sequence from inside to outside.

In one of the embodiments, an end of each group of the infrared heating lamp tubes away from the center of the mounting base plate forms a circle or a rectangle.

In one of the embodiments, each infrared heating lamp tube is evenly arranged on the mounting base plate in a circumferential direction.

In one of the embodiments, the infrared heating lamp tube has an L-shaped structure.

In one of the embodiments, a bracket for supporting the infrared heating lamp tube is provided at the end of the infrared heating lamp tube pointing to the center of the mounting base plate, the bracket is mounted on the mounting base plate.

In one of the embodiments, the mounting base plate is provided with mounting through holes through which the infrared heating lamp tubes pass, and the end of the infrared heating lamp tube away from the center of the mounting base plate passes through the mounting through hole.

In one of the embodiments, the infrared heating lamp tube is hermetically connected with the mounting through hole.

In one of the embodiments, the device further includes a power regulator connected to the infrared heating lamp tubes for controlling each infrared heating lamp tube or each group of the infrared heating lamp tubes.

In one of the embodiments, an arrangement height of each infrared heating lamp tube on the mounting base plate is the same.

### (III) Advantageous Effects

The technical solutions of the present disclosure above at least have the following advantages:

According to the infrared heating lamp tube device described of the present disclosure, a plurality of infrared heating lamp tubes are radially arranged in a circumferential direction with the center of the mounting base plate as a circle center, such arrangement of the infrared heating lamp tubes can achieve a better control of temperature uniformity, and meet the requirement of higher process uniformity.

### BRIEF DESCRIPTION OF THE DRAWINGS

FIG. 1 is a structural diagram of the infrared heating lamp tube device of an embodiment of the present disclosure;

FIG. 2 is a top view of the infrared heating lamp tube device of an embodiment of the present disclosure;

FIG. 3 is a structural diagram of the infrared heating lamp tube of the infrared heating lamp tube device of an embodiment of the present disclosure;

In the drawings: 1: mounting base plate; 2: infrared heating lamp tube; 201: first group of infrared heating lamp tubes; 202: second group of infrared heating lamp tubes; 203: third group of infrared heating lamp tubes; 204: fourth group of infrared heating lamp tubes; 205: fifth group of infrared heating lamp tubes.

### DETAILED DESCRIPTION

In order to make the objectives, technical solutions, and advantages of the embodiments of the present disclosure clearer, the technical solutions of the embodiments of the present disclosure will be described clearly with reference to the accompanying drawings hereinafter. Obviously, the described embodiments are merely some but not all of the embodiments of the present disclosure. On the basis of the embodiments of the present disclosure, all other embodiments obtained by the person of ordinary skill in the art without creative work shall fall within the protection scope of the present disclosure.

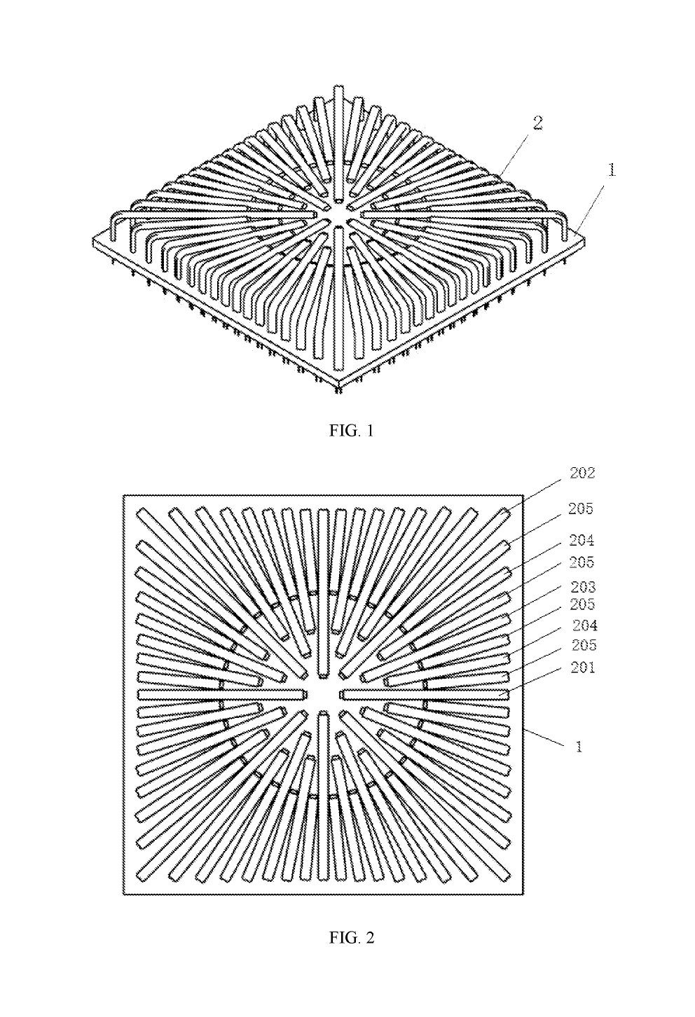

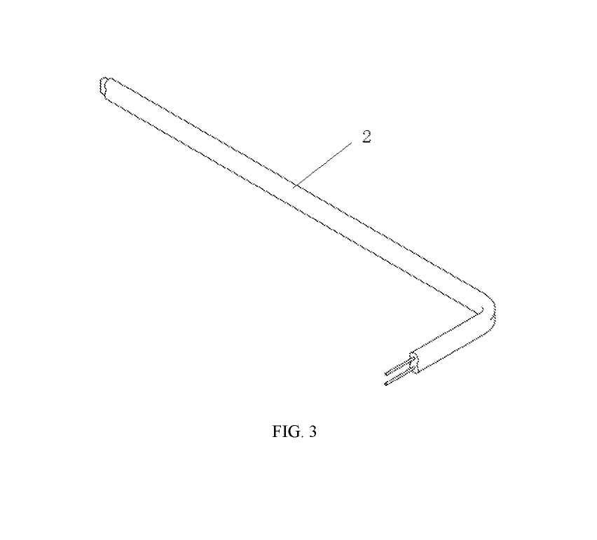

As shown in FIG. 1-3, the embodiments of the present disclosure provide an infrared heating lamp tube device, including a mounting base plate 1 and a plurality of infrared heating lamp tubes 2 mounted on the mounting base plate 1. The plurality of the infrared heating lamp tubes 2 are radially arranged in a circumferential direction with the center of the mounting base plate 1 as a circle center, and an extension line of each infrared heating lamp tube 2 is directed toward the center of the mounting base plate 1.

Each infrared heating lamp tube 2 is evenly arranged on the mounting base plate 1 in a circumferential direction, that is, the angle between any two adjacent infrared heating lamp tubes 2 is equal.

The infrared heating lamp tube device described in the embodiment of the present disclosure is installed inside the process deposition chamber, the wafer carrier for carrying the wafer substrate is parallel to the infrared heating lamp tube device and is horizontally transferred to the process position, at this time the wafer carrier is locate right above the infrared heating lamp tube device. By receiving the radiant energy of the infrared heating lamp tubes, the wafer susceptor heats the wafer substrate to the process temperature. By arranging the plurality of infrared heating lamp tubes 2 radially in a circumferential direction with the center of the mounting base plate 1 as the circle center, the infrared heating lamp tube device described in the present embodiment improves the temperature distribution uniformity in the chamber.

To describe further, the infrared heating lamp tubes 2 are divided into at least two groups. An end of each group of the infrared heating lamp tubes 2 pointing to the center of the mounting base plate 1 forms a circle, and each circle is arranged in sequence from the inside to the outside. An end of each group of the infrared heating lamp tubes 2 away from the center of the mounting base plate 1 forms a circle or a rectangle.

In the present embodiment, the infrared heating lamp tubes are divided into five groups, which are a first group of the infrared heating lamp tubes 201, a second group of the infrared heating lamp tubes 202, a third group of the infrared heating lamp tubes 203, a fourth group of the infrared heating lamp tubes 204 and a fifth group of the infrared heating lamp tubes 205. Each group of the infrared heating lamp tubes can be arranged in an intersecting manner between each other, and the number of the infrared heating lamp tubes in each group can be adjusted according to actual needs.

An end of the first group of the infrared heating lamp tubes 201 pointing to the center of the mounting base plate 1 forms a first circle, an end of the second group of the infrared heating lamp tubes 202 pointing to the center of the mounting base plate 1 forms a second circle, an end of the third group of the infrared heating lamp tubes 203 pointing to the center of the mounting base plate 1 forms a third circle, an end of the fourth group of the infrared heating lamp tubes 204 pointing to the center of the mounting base plate 1 forms a fourth circle, and an end of the fifth group of the infrared heating lamp tubes 205 pointing to the center of the mounting base plate 1 forms a fifth circle. The first circle, the second circle, the third circle, the fourth circle and the fifth circle are arranged in sequence from the inside to the outside. Wherein, the heating temperature in the center area of the mounting base plate 1 is provided by the first group of the infrared heating lamp tubes 201 and the second group of the infrared heating lamp tubes 202, the heating temperature in the middle area of the mounting base plate 1 is provided by the third group of the infrared heating lamp tubes 203 and the fourth group of the infrared heating lamp tubes 204, and the heating temperature in the peripheral area of the mounting base plate 1 is provided by the fifth group of the infrared heating lamp tubes 205, thereby the whole heating area of the mounting base plate 1 is formed.

The device further includes a power regulator connected to the infrared heating lamp tubes for controlling each infrared heating lamp tube or each group of the infrared heating lamp tubes. The temperature gradients in the center area, the middle zone and the peripheral area of the heating area can be achieved by independent power regulation control of the infrared heating lamp tubes in different areas. Therefore, the circumferential temperature distribution uniformity of the entire heating area can be controlled by regulating the power of each infrared heating lamp tube or the power of each group of the infrared heating lamp tubes with the power regulator.

The arrangement height of each infrared heating lamp tube 2 on the mounting base plate 1 is the same, and the arrangement height of the infrared heating lamp tubes 2 are parallel to the wafer carrier track. Each infrared heating lamp tube 2 can be connected to the power supply independently or regionally. An independently regulating for the temperature distribution of each infrared heating lamp tube 2 or region can be achieved by the power regulator independently adjusting the amount of electricity flowing to each infrared heating lamp tube 2 or the infrared heating lamp tubes in a certain area.

The length and power of the infrared heating lamp tubes in different groups may vary according to the shape of the wafer carrier. The mounting base plate 1 may adopt a rectangular or circular structure, correspondingly, the end of each infrared heating lamp tube 2 away from the center of the mounting base plate 1 forms a circle or a rectangle matching the shape of the mounting base plate 1.

Since the shape of most of the wafer carriers currently used is rectangle, in the present embodiment, the mounting base plate 1 adopts a rectangular structure; correspondingly, the end of each infrared heating lamp tube 2 away from the center of the mounting base plate 1 forms a rectangle matching the shape of the mounting base plate 1, thereby the length and size of each infrared heating lamp tube 2 can be adjusted as needed.

In the present embodiment, the infrared heating lamp tube 2 has an L-shaped structure, and a heating filament of the infrared heating lamp tube 2 is single-ended.

The end of the infrared heating lamp tube 2 away from the center of the mounting base plate 1 is a filament lead-out end, which is a cold-end. The end needs to pass through the mounting base plate 1, and the mounting base plate 1 is provided with mounting through holes through which the infrared heating lamp tubes 2 pass.

The infrared heating lamp tube 2 is hermetically connected with the mounting through hole, by which the atmosphere is isolated when the entire infrared heating lamp tube device is mounted on the process chamber. In the present embodiment, the infrared heating lamp tube 2 is hermetically connected with the mounting through hole with an 0-shaped sealing ring.

A bracket for supporting the infrared heating lamp tube 2 is provided at the end of the infrared heating lamp tube 2 pointing to the center of the mounting base plate 1. The bracket is fixedly mounted on the mounting base plate 1. The bracket may be made of metallic materials, and may also be made of non-metallic materials resistant to heat, such as ceramics.

In summary, according to the infrared heating lamp tube device described in the embodiments of the present disclosure, a plurality of infrared heating lamp tubes are radially arranged in a circumferential direction with the center of the mounting base plate as a circle center, such arrangement of the infrared heating lamp tubes can achieve a better control of temperature uniformity, and meet the requirement of higher process uniformity.

Finally, it should be noted that the embodiments above are only used to illustrate rather than to limit the technical solutions of the present disclosure; although the present disclosure has been described in detail with reference to the foregoing embodiments, those of ordinary skill in the art should understand that they can still modify the technical solutions described in the foregoing embodiments, or equivalently replace some of the technical features therein; and these modifications or replacements do not separate the essence of the corresponding technical solutions from the spirit and scope of the technical solutions of each of the embodiments of the present disclosure.

1. An infrared heating lamp tube device, comprising a mounting base plate and a plurality of infrared heating lamp tubes mounted on the mounting base plate, wherein the plurality of infrared heating lamp tubes are radially arranged in a circumferential direction with a center of the mounting base plate as a circle center, and an extension line of each infrared heating lamp tube is directed toward the center of the mounting base plate.

2. The infrared heating lamp tube device of claim 1, wherein the infrared heating lamp tubes are divided into at least two groups, an end of each group of the infrared heating lamp tubes pointing to the center of the mounting base plate forms a circle, and each circle is arranged in sequence from inside to outside.

3. The infrared heating lamp tube device of claim 2, wherein an end of each group of the infrared heating lamp tubes is away from the center of the mounting base plate forms a circle or a rectangle.

4. The infrared heating lamp tube device of claim 1, wherein each infrared heating lamp tube is evenly arranged on the mounting base plate in a circumferential direction.

5. The infrared heating lamp tube device of claim 1, wherein the infrared heating lamp tube has an L-shaped structure.

6. The infrared heating lamp tube device of claim 5, wherein a bracket for supporting the infrared heating lamp tube is provided at the end of the infrared heating lamp tube pointing to the center of the mounting base plate, and the bracket is mounted on the mounting base plate.

7. The infrared heating lamp tube device of claim 5, wherein the mounting base plate is provided with mounting through holes through which the infrared heating lamp tubes pass, and the end of the infrared heating lamp tube is away from the center of the mounting base plate passes through the mounting through hole.

8. The infrared heating lamp tube device of claim 7, wherein the infrared heating lamp tube is hermetically connected with the mounting through hole.

9. The infrared heating lamp tube device of claim 2, further comprises a power regulator connected to the infrared heating lamp tubes for controlling each infrared heating lamp tube or each group of the infrared heating lamp tubes.

10. The infrared heating lamp tube device of claim 1, wherein an arrangement height of each infrared heating lamp tube on the mounting base plate is the same.
